(19) United States
(12) Patent Application Publication
(10) Pub. No.: US 2025/0172629 A1
(43) Pub. Date: May 29, 2025

(54) METHOD AND DEVICE FOR GENERATING A DIGITAL PASSPORT OF A LITHIUM-ION BATTERY CELL

(71) Applicant: COMMISSARIAT A L'ENERGIE ATOMIQUE ET AUX ENERGIES ALTERNATIVES, Paris (FR)

(72) Inventors: Jonathan DESEURE, Grenoble Cedex 09 (FR); Lauriane BICHOT, Grenoble Cedex 09 (FR); Maxime MONTARU, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/959,963

(22) Filed: Nov. 26, 2024

(30) Foreign Application Priority Data
Nov. 29, 2023 (FR) 2313263

(51) Int. Cl. G01R 31/392; G01R 31/36; G01R 31/367; G01R 31/382

(52) U.S. Cl. CPC G01R 31/392; G01R 31/3648; G01R 31/367; G01R 31/382

(57) ABSTRACT

A method for generating a “digital passport” of a cell of a Lithium-Ion battery. The digital passport is in the form of a computer file including a set of incidence values representative of a history of states-of-health of the cell over its service life. The method includes, for each CV phase of a set of CC-CV charging cycles of the cell:
collecting several measurements forming a floating current signal,
deriving the floating current signal,
decomposing into empirical modes the derivative of the floating current,
determining an incidence value representative of a state-of-health of the cell, for the considered CV phase, based on the intrinsic components obtained by the decomposition,
memorizing in the computer file the incidence value thus determined with a date of occurrence.

### TECHNICAL FIELD

The present invention relates to the field of management of “Lithium-Ion” type batteries. More particularly, a method and a device are provided for generating a digital passport of a Lithium-Ion battery cell, in order to offer a synthetic and easily exploitable representation of the state-of-health of the cell. In particular, this digital passport could be used to assess the possibility of reusing the cell in a second service life.

### BACKGROUND

The draft regulation on batteries 2020/353 (COD), repealing the European directive 2006/66/EC and modifying the regulation of the European Union (EU) No. 2019/1020, aims to improve the management of lithium batteries and wastes of these batteries in the European Union. The draft provides for a series of measures intended in particular to increase the rate of battery collection, to reduce the amount of hazardous substances contained in batteries and to improve recycling of batteries. This allows protecting the environment and preserving natural resources. This draft regulation on batteries is currently being examined by the European parliament and the Council of the European Union.

This draft regulation also introduces the concept of “battery digital passport” allowing supplying synthetic and easily exploitable data about the safety of the battery, of dismantlement thereof and/or of reuse thereof in a second service life.

Nonetheless, there is no specific recommendation on the exact nature of the data that the digital passport should contain to give an insight on the state-of-health of the battery and on the possibility, or not, of reusing it in a second service life.

Many diagnosis methods have already been known to estimate a state-of-health of a lithium battery. In general, these diagnosis methods are based on voltage signals measured at the level of the battery, like for example in the patent applications US 2017/146608 A1 and US 2022/0381849 A1. In turn, the patent application EP 3324197 A1 describes a method for determining the state-of-health of a battery cell according to a ratio between a charge variation and a current difference measured between two time points of a CV phase (constant-voltage charging phase) of a CC-CV cycle (a charging cycle including a constant-current charging phase followed by a constant-voltage charging phase). However, the reliability of these methods is not always fully satisfactory.

### SUMMARY

An objective of the present invention is to overcome all or part of the drawbacks of the prior art, in particular those set out hereinbefore.

To this end, and according to a first aspect, a method is provided by the present invention for generating a digital passport of a cell of a Lithium-Ion battery. The digital passport is in the form of a computer file including a set of incidence values representative of a history of states-of-health of the cell over a first service life of the cell. The method includes, for each “constant-voltage” phase (CV phase), a set of “constant current-constant voltage” charging cycles (CC-CV charging cycles) of the cell over its first service life:
collecting a plurality of current measurements performed at the level of the cell during the considered CV phase, said plurality of measurements forming a “floating current” signal,
deriving the floating current signal to obtain a floating current derivative signal,
decomposing into empirical modes the floating current derivative signal in order to obtain therefrom a representation in the form of a sum of a residual signal and of one or more intrinsic component(s),
determining an incidence value representative of a state-of-health of the cell, for the considered CV phase, based on the intrinsic components thus obtained,
memorizing in a computer file the determined incidence value associated with a piece of information on the occurrence time point of the considered CV phase.

In some particular modes of implementation, the invention may further include one or more of the following features, considered separately or according to any technically-feasible combinations.

In particular modes of implementation, the determination of the incidence value, for the considered CV phase, comprises:
calculating an energy for each intrinsic component,
calculating a total intrinsic energy equal to a sum of the energies of the intrinsic components,
determining the incidence value, for the considered CV phase, according to the total intrinsic energy thus calculated.

In particular modes of implementation, the determination of the incidence value, for the considered CV phase, comprises:
calculating a spectral density for each intrinsic component,
calculating a total intrinsic spectral density equal to a sum of the spectral densities of the different intrinsic components,
determining the incidence value, for the considered CV phase, according to the total intrinsic spectral density thus calculated.

In particular modes of implementation, the total intrinsic spectral density is normalized with respect to a maximum value of the total intrinsic spectral density. In particular modes of implementation, for each intrinsic component, the spectral density of the intrinsic component is calculated based on a Hilbert transform of the intrinsic component.

The proposed method clearly stands out from the conventional methods as it is based on the analysis of the derivative of the floating current during a CV phase of a CC-CV charging cycle. At first glance, nothing suggests that this signal contains relevant information for monitoring the state-of-health of the cell.

The empirical mode decomposition is particularly well suited to the analysis of this signal. This decomposition further has the advantage of being relatively fast and efficient in terms of computing capacity.

The evolution of the total intrinsic energies or of the total intrinsic spectral densities over the different CV phases of the first service life of the cell supply a valuable database for exploring the history of the cell and estimating its state-of-health. Although it is particularly synthetic (the volume of the data to be memorized remains relatively small), this database gives very relevant indications on the state-of-health of the cell and on the possibility of reusing it in a second service life.

In particular modes of implementation, the method further includes, for each CV phase, estimating a statistical reliability of the CV phase according to the intrinsic components of the floating current derivative signal. The CV phase is filtered if it is found to be unreliable.

In particular modes of implementation, the statistical reliability of the CV phase is estimated according to an entropy calculated for a sum of the intrinsic components of the floating current derivative signal.

In particular modes of implementation, the statistical reliability of the CV phase is estimated by comparing the total intrinsic energy with a predetermined energy threshold, or with the total intrinsic energies calculated for all or part of the previous CV phases.

Filtering the CV phases found to be statistically unreliable allows limiting the number of incidence values to be memorized and, consequently, limiting the size of the digital passport of the cell. This also allows avoiding introducing aberrant values in the digital passport of the cell.

In particular modes of implementation, the method includes a step of detecting at least one failure of the cell over its first service life based on the incidence values memorized in the computer file forming the digital passport of the cell.

In particular modes of implementation, the detection of said at least one failure includes comparing the incidence value with a predetermined incidence threshold, for one or more consecutive CV phase(s).

In particular modes of implementation, the detection of said at least one failure includes comparing a distance between the incidence value and an average incidence value with a predetermined distance threshold, for one or more consecutive CV phase(s).

In particular, the detection of one or more failure(s) of the cell over its first service life, based on the digital passport of the cell, could allow estimating the possibility, or not, of reusing the cell in a second service life (for example according to the number and/or the significance of the observed failures).

In particular modes of implementation, when at least one failure is detected, the method further includes verifying whether said at least one detected failure is related to the environment in which the cell has evolved.

In particular modes of implementation, the verification of whether said at least one detected failure is related to the environment comprises comparing, for a given period, incidence values memorized for said cell during said period with incidence values determined for at least one other cell subjected to the same environment during said period.

In particular modes of implementation, the verification of whether said at least one detected failure is related to the environment comprises comparing, for a given period, environment measurements performed and memorized during said period with a predetermined threshold.

Indeed, it might be advantageous to know whether some failures undergone by the cell over its first service life are related to the environment in which the cell has evolved. Indeed, failures related to the environment are generally less detrimental to the possibility of reusing the battery in a second service life than failures intrinsic to the cell (for example, failures related to a manufacturing defect or to a precocious degradation of the cell).

In particular modes of implementation, the method includes a step of determining, based on the digital passport of the cell, whether the cell could, or not, be reused for a second service life.

According to a second aspect, a device is provided by the present invention for generating a “digital passport” of a cell of a Lithium-Ion battery. The digital passport is in the form of a computer file including a set of incidence values representative of a history of states-of-health of the cell over a first service life of the cell. The device includes:
a memory adapted to memorize the computer file,
a battery management system configured to supply current measurements performed at the level of the cell during a CV phase of a CC-CV charging cycle of the cell,
a computing unit connected to the memory and to the battery management system, said computing unit being configured to implement the method according to any one of the previously-described modes of implementation.

### BRIEF DESCRIPTION OF THE DRAWINGS

The invention will be better understood upon reading the following description, given as a non-limiting example, and made with reference to FIGS. 1 to 14 which show:

FIG. 1 is a schematic representation of the main steps of an example of implementation of the method according to the invention for generating a digital passport of a Lithium-Ion battery cell,

FIG. 2 is a schematic representation of a particular mode of implementation of the step of determining an incidence value,

FIG. 3 a schematic representation of another particular mode of implementation of the step of determining an incidence value,

FIG. 4 a graph representing the current flowing in a Lithium-Ion battery cell over four successive CC-CV charging cycles,

FIG. 5 a graph representing the floating current flowing in a Lithium-Ion battery cell over a CV phase of a CC-CV charging cycle of the cell,

FIG. 6 a graph representing the derivative of the floating current represented in FIG. 5,

FIG. 7 a graph representing a decomposition into empirical modes of the floating current derivative represented in FIG. 6,

FIG. 8 a first example of representation of incidence values determined for a Lithium-Ion battery cell during a given period,

FIG. 9 a second example of representation of incidence values determined for a Lithium-Ion battery cell during a given period,

FIG. 10 a third example of representation of incidence values determined for a Lithium-Ion battery cell during a given period,

FIG. 11 a fourth example of representation of incidence values determined for a Lithium-Ion battery cell during a given period,

FIG. 12 a graph representing the evolution over time of the incidence value of a battery cell, as well as the evolution over tome, during the same period, of the temperature experienced by the cell,

FIG. 13 a graph representing another example of the evolution over time of the incidence value of a battery cell, as well as the evolution over time, during the same period, of the temperature experienced by the cell,

FIG. 14 a schematic representation of a device according to the invention allowing generating a digital passport for a cell of a Lithium-Ion battery.

In these figures, identical references from one figure to another designate identical or similar elements. For clarity, the elements shown are not necessarily plotted to the same scale, unless stated otherwise.

### DETAILED DESCRIPTION

As indicated before, the present application provides a method and a device for generating a “digital passport” of a cell of a Lithium-Ion battery.

A charging cycle of a Lithium-Ion battery cell conventionally includes two phases: a first phase of constant-current charging, or CC phase (CC stands for “Constant Current”) and a second phase of constant-voltage charging, or CV phase (CV stands for “Constant Voltage”). We then talk about a CC-CV charging cycle. In the present invention, we focus on the current that flows in the cell during the CV phase. In general, this current is called “floating current”.

Although the first charging phase (CC phase) is conventionally performed at constant current, more elaborate charging schemes could exist during this first phase, with an evolution of the current for example to maximize the charging speed while remaining in the charging domain compatible with the accumulator. The end of the first charging phase is then marked by reaching a voltage threshold that triggers toggling into the second phase of constant-voltage charging (CV phase). For simplicity, it will be considered that these particular cases of the first charging phase are also covered by the expression CC-CV “constant current-constant voltage” charging used in this application.

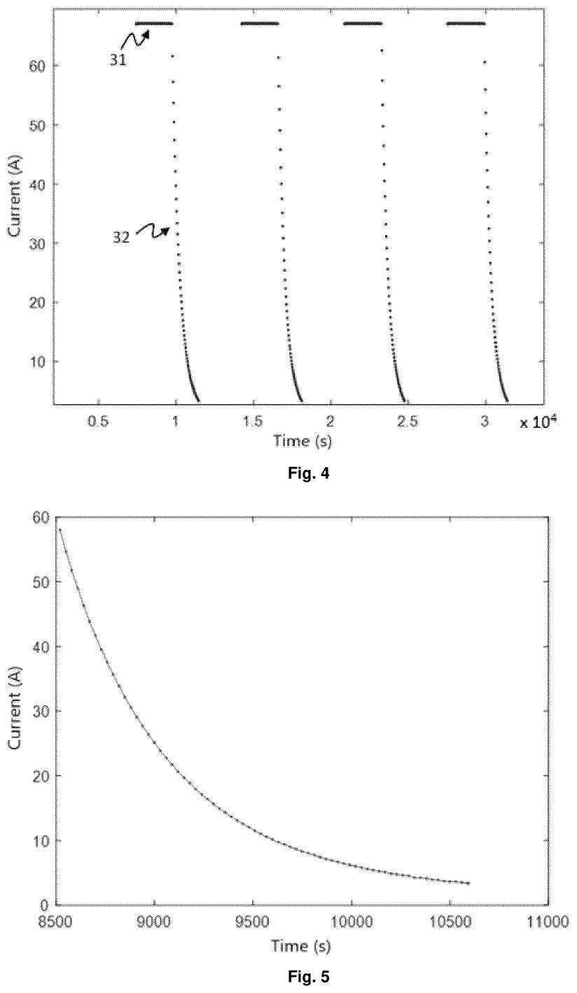

FIG. 4 is a graph representing four successive CC-CV charging cycles of a Lithium-Ion battery cell. The current that flows in the cell is represented in the ordinate axis (in amps) and the time is represented in the abscissa axis (in seconds). Each cycle includes a CC phase 31 and a CV phase 32. As illustrated in the graph of FIG. 4, the current that flows in the cell during the CC phase 31 is substantially constant, and it features an exponential decrease during the CV phase 32. FIG. 5 is a graph showing in a more detailed manner the CV phase 32 of a CC-CV charging cycle of the cell.

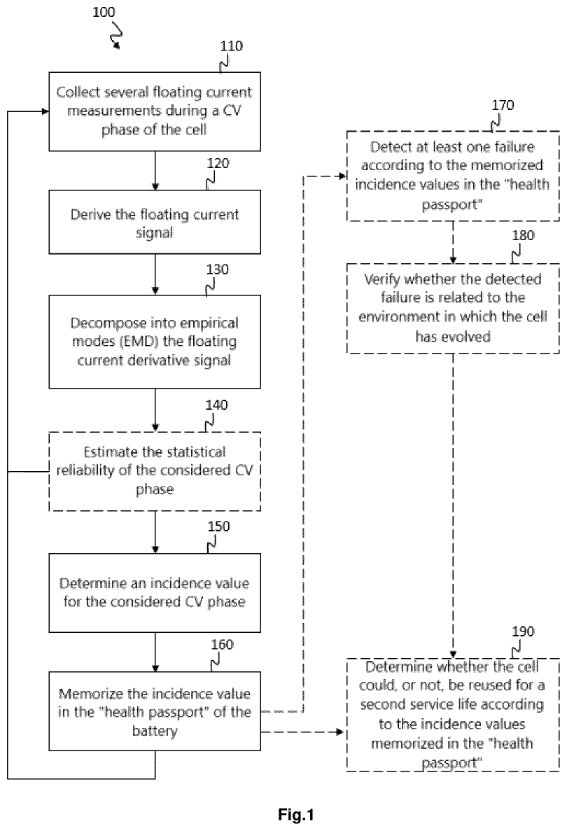

FIG. 1 schematically represents the main steps of an example of implementation of a method 100 according to the invention for generating a digital passport of a cell of a Lithium-Ion battery.

As illustrated in FIG. 1, the method 100 includes the following steps, for each CV phase of a set of CC-CV charging cycles over a first service life of the cell:
collecting 110 several floating current measurements during the considered CV phase,
deriving 120 the floating current thus obtained,
decomposing into empirical modes 130 (EMD, standing for “Empirical Mode Decomposition”) of the derivative of the floating current,
determining 150 an incidence value based on the intrinsic components obtained by the EMD decomposition,
memorizing 160 the incidence value in a computer file.

The computer file thus obtained forms a digital passport for the cell. The incidence values memorized in this passport are representative of a history of states-of-health of the cell over its first service life.

These steps may be implemented for the CV phase of all of the CC-CV charging cycles undergone by the cell over its first service life. Nonetheless, there is nothing preventing, in one variant, from implementing these steps only for a subset of all charging cycles, for example only for one charging cycle out of two.

For example, the floating current measurements during the CV phase are performed by a battery management system (BMS) connected to the cell. For example, the measurements are performed with an acquisition frequency comprised between one and sixty second(s), during an acquisition duration of ten to sixty minutes. Nonetheless, there is nothing preventing from making the measurements with a different acquisition frequency, and/or during a different acquisition duration. It is advantageous to use a number of measurements comprised between thirty and fifty per CV phase (using a larger number of measurements does not necessarily imply a significant improvement of the method, using a smaller number of measurements could however limit the performances of the method). All of the measurements collected during the collection step 110 form a “floating current” signal. The graph of FIG. 5 represents an example of a floating current signal obtained in the collection step 110.

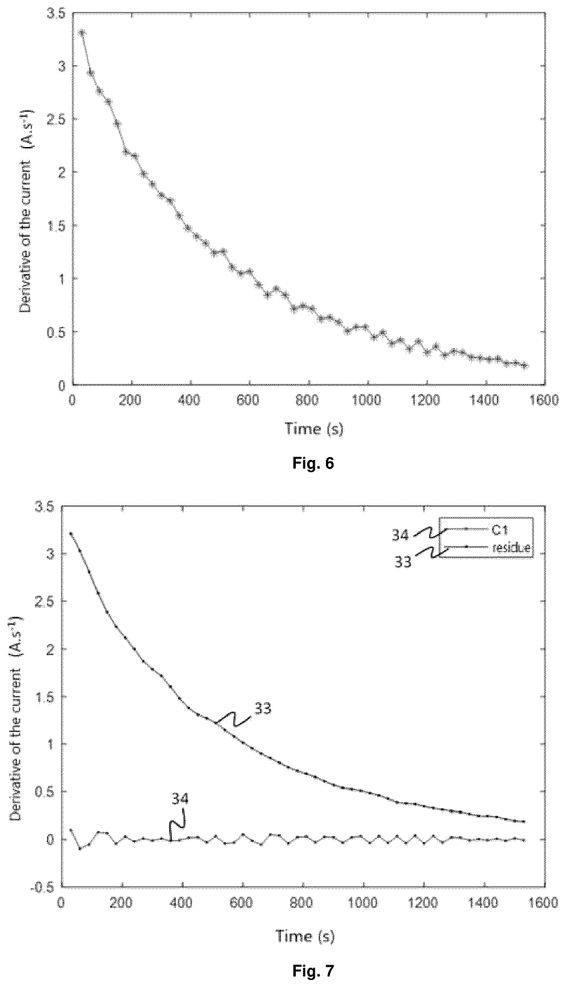

In the derivation step 120, the floating current signal obtained in step 110 is derived to obtain a floating current derivative signal. The graph of FIG. 6 represents an example of a floating current derivative signal obtained in the derivation step 120 (it consists of the floating current signal derivative represented in the graph of FIG. 5).

In step 130, the floating current derivative signal is decomposed according to an empirical mode decomposition. It should be noted that the floating current signal is generally too “smooth” and that it hardly enables an empirical mode decomposition, this is why we focus on its derivative, even though, at first glance, nothing would suggest that this floating current derivative signal would contain relevant information on the state-of-health of the cell.

The empirical mode decomposition consists in decomposing a signal in the form of a sum of functions, in a similar way as the Fourier series decomposition or the wavelet decomposition.

One of the particularities of the empirical mode decomposition is that the function base according to which the signal is decomposed is not known a priori, but it is built in an adaptive way according to the properties of the signal.

The empirical mode decomposition corresponds to the first portion of the Hilbert-Huang transform (HHT). The empirical mode decomposition consists in decomposing a signal in the form of a sum of a residual signal and of intrinsic mode functions (IMF). In the present application, these intrinsic mode functions are also called “intrinsic components”.

As indicated before, the intrinsic components are not defined analytically. They are rather determined in an adaptive way according to the properties of the signal.

An intrinsic component (IMF) resulting from an empirical mode decomposition (EMD) should meet the following requirements:
The number of extrema (i.e. the sum of the number of the local maxima and of the number of the local minima) and the number of zero crossings of the intrinsic component should be equal or differ at most by one;
at any point of the intrinsic component, the average value of the envelope defined by the local maxima and of the envelope defined by the local minima is zero.

A signal s(t) decomposed by EMD could then be written in the form:

$$s ( t ) = r ( t ) + {\sum }_{i = 1}^{N} {c}_{i} ( t )$$

In this expression, r(t) corresponds to the residual signal, N is the number of intrinsic components of the EMD decomposition, and ca is the intrinsic component with the index i. Each successive intrinsic component cᵢ(t) contains frequency oscillations lower than those of the previous one. The residual signal corresponds to a general tendency of the signal s(t).

The empirical mode decomposition includes a series of sifting processes. The first sifting process directly takes on the signal s(t) as input. The sifting process corresponds to identifying all of the local extrema of the input signal, and to connecting the local maxima, respectively the local minima, via a cubic spline interpolation, in order to obtain an upper envelope, respectively a lower envelope. An average between the upper envelope and the lower envelope could then be calculated and subtracted from the input signal. If the obtained intermediate signal (subtraction of the input signal with the average of the upper and lower envelopes) is not an intrinsic component, the sifting process is reiterated on the intermediate signal (which therefore becomes the input signal of a new sifting process) until obtaining an intrinsic component. The sifting processes are repeated until obtaining the last intrinsic component, i.e. for example until the intermediate signal becomes monotone or it includes only one single local extremum. The remaining signal then corresponds to the residual signal r(t).

A stop criterion may be defined for the sifting process. For example, the stop criterion is met if the standard deviation between the results of two successive sifting processes is lower than or equal to a predetermined stop threshold. The stop threshold may typically be comprised between 0.2 and 0.3.

The document “The empirical mode decomposition and the Hilbert spectrum for non-linear and non-stationary time series analysis”, by Norden E. Huang et al., Proc. R. Soc. Lond. A (1998) 454, p. 903-995, describes in detail the empirical mode decomposition, in particular in its sections 4 and 5.

Empirical mode decomposition algorithms are available in programming libraries, for example in the MATLAB or Python language.

The graph of FIG. 7 represents an example of empirical mode decomposition of the floating current derivative signal represented in FIG. 6. In the considered example illustrated in FIG. 7, the empirical mode decomposition has resulted in one single intrinsic component 34 (c₁) and a residual signal 33. It should be noted that, in other examples, a larger number of intrinsic components could be obtained. Nonetheless, the number of intrinsic components generally remains less than five. It is advantageous to set the stop threshold at a relatively low level, in the range of 0.2, to extract as much information as possible from the floating current derivative signal. Using a lower stop threshold imposes particularly long calculation times.

The intrinsic components obtained in step 130 are then used in step 150 to determine an incidence value representative of the state-of-health of the cell for the considered CV phase.

Different methods may be considered to determine the incidence value associated with the considered CV phase.

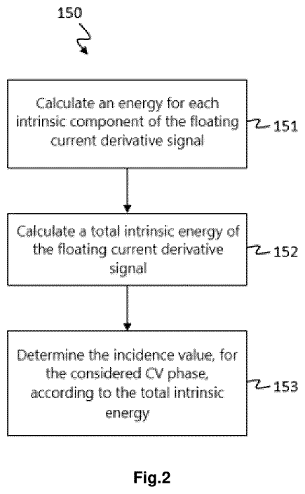

According to a first example, and as illustrated in FIG. 2, the determination 150 of the incidence value may include:
calculating 151 an energy for each intrinsic component,
calculating 152 a total intrinsic energy equal to the sum of the energies of the intrinsic components, and
determining 153 the incidence value according to the total intrinsic energy thus calculated.

For example, the energy Eᵢ of an intrinsic component cᵢ corresponds to the integral of the square of the amplitude of the intrinsic component cᵢ over the acquisition duration of the considered CV phase:

$${E}_{i} = \int {\vert {c}_{i} ( t ) \vert}^{2} d t$$

The total intrinsic energy E of the considered CV phase could then be written in the form:

$$E = {\sum }_{i = 1}^{N} {E}_{i}$$

It should be noted that there is nothing preventing, in one variant, from calculating the total intrinsic energy E by summing up the energies of only a subset of the intrinsic components obtained by the EMD decomposition (for example, by considering only a predefined maximum number of the first intrinsic components obtained by the EMD decomposition).

The incidence value of the considered CV phase may then correspond to the total intrinsic energy of the CV phase, or to an average value of the total intrinsic energy for all or part of the total intrinsic energies calculated for previous CV phases.

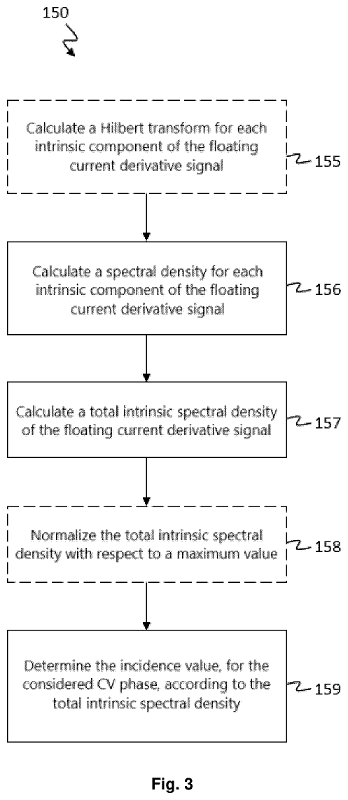

According to a second example, and as illustrated in FIG. 3, the determination 150 of the incidence value may include:
calculating 156 a spectral density for each intrinsic component,
calculating 157 a total intrinsic spectral density equal to the sum of the spectral densities of the intrinsic components (or possibly equal to the sum of the spectral densities of the intrinsic components of only one subset of the intrinsic components), and
determining 159 the incidence value according to the total intrinsic spectral density thus calculated.

For example, the incidence value of the considered CV phase may correspond to the surface area of the total intrinsic spectral density of the CV phase, or to an average value of the surface area of the total intrinsic spectral density for all or part of the total intrinsic energies calculated for previous CV phases. The incidence value could also correspond to a set of samples of the total intrinsic spectral density.

Nonetheless, there is nothing preventing from determining the incidence value of a CV phase by combining the total intrinsic energy and the total intrinsic spectral density. For example, the incidence value may correspond to a pair of values including the total intrinsic energy and the surface area (or a set of samples) of the total intrinsic spectral density of the considered CV phase.

In particular, the spectral densities of the different intrinsic components may be calculated by the Welch method. Nonetheless, there is nothing preventing from using other spectral density estimation methods, like for example the Bartlett or Blackman-Tukey methods.

Optionally, the spectral density of each intrinsic component may be calculated based on a Hilbert transform of the intrinsic component. For this purpose, and as illustrated in FIG. 3, the step of determining 150 the incidence value includes an additional step of calculating 155 a Hilbert transform of each intrinsic component of the floating current derivative signal, prior to the step of calculating 156 the spectral densities of the intrinsic components.

The Hilbert transform allows extending a real signal in the complex domain. The transformed signal then features zero amplitude responses at the zero frequencies. This allows avoiding artifacts during the exploitation of the information contained in the processed signal. Thus, the Hilbert transform allows optimizing the spectral density calculation.

Algorithms enabling these Hilbert transform and spectral density estimation calculations are available in programming libraries, for example in MATLAB or in Python.

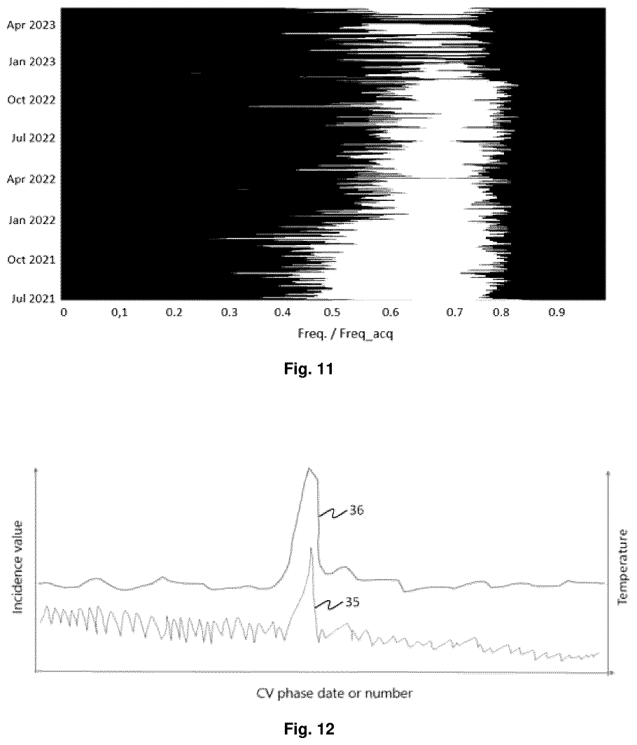

Furthermore, and as illustrated in FIG. 3 by the optional step 158, the total intrinsic spectral density may be normalized, for example with respect to a maximum value of the total intrinsic spectral density. It is particularly advantageous to make this normalization when it is desired to “map” the total intrinsic spectral density and compare the different mappings obtained for different CV phases. A mapping of the total intrinsic spectral density corresponds to a representation of the amplitude, of the spectral position and of the spectral width of the different peaks of the total intrinsic spectral density. This mapping may be carried out based on a set of samples of the total intrinsic spectral density. FIG. 11 is an example of mapping of the total intrinsic spectral densities calculated for different dates (this graph will be described in detail later on).

As illustrated in FIG. 1, the incidence value determined for each CV phase in step 150 is memorized, in step 160, in the computer file forming the digital passport of the cell. In this computer file, each incidence value is associated with a piece of information on the occurrence time point of the CV phase to which it corresponds. For example, this piece of information may correspond to an occurrence date, with the day and possibly the time at which the CV phase has occurred. This piece of information could quite simply correspond to a CV phase number (this number being incremented at each new CV phase undergone by the cell over its first service life).

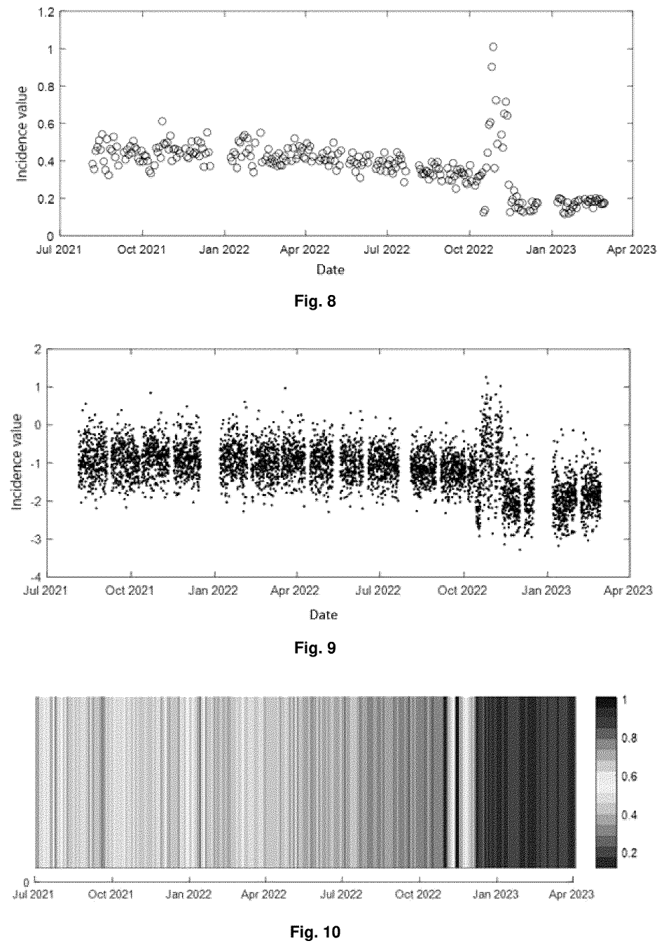

FIGS. 8 and 9 show examples of incidence values, associated with the dates of the CV phases for which they have been determined, for a Lithium-Ion battery cell during a given period (between July 2021 and April 2023).

In the graph of FIG. 8, each incidence value corresponds to an average of the total intrinsic energies calculated for twenty consecutive CV phases.

In the graph of FIG. 9, each incidence value corresponds to the surface area of the total intrinsic spectral density calculated for each of the CV phases successively undergone by the cell during the considered period.

Hence, the number of incidence values shown in FIG. 8 is less than the number of incidence values shown in FIG. 9 (in FIG. 8, an incidence value corresponds to a twenty consecutive CV phases whereas, in FIG. 9, an incidence value corresponds to one single CV phase).

All of the incidence values shown in FIGS. 8 and 9 may correspond to a digital passport of the cell. The volume of data required to form this passport is relatively small, for example in the range of a few kilobytes to a few tens of kilobytes.

FIGS. 10 and 11 illustrate other examples of representation of the incidence values. As illustrated in FIG. 10, it is possible to represent the incidence values in the form of a graphic chart. The longitudinal axis of the chart represents the evolution of time. A color code represents the incidence value at a given date (for example, the value of the total intrinsic energy, or the value of the surface area of the total intrinsic spectral density).

As illustrated in FIG. 11, it is also possible to represent a mapping of the normalized total intrinsic spectral densities. The time is represented in the ordinate axis. The abscissa axis represents the ratio between the frequency and the acquisition frequency. A color code may allow representing the amplitude of a peak of the spectral density at a given frequency. Thus, this allows mapping the amplitude, the spectral position and the spectral width of the different peaks of the normalized total intrinsic spectral density. This mapping may be done based on a set of samples of the normalized total intrinsic spectral density. In the case where the digital passport of a cell memorizes, for each considered CV phase, samples of the normalized total intrinsic spectral density, the volume of required data becomes larger, for example a few hundred kilobytes to a few megabytes.

As illustrated in FIG. 1, the method 100 according to the invention may also include an optional step of estimating 140 a statistical reliability of a CV phase, and a filtering of the CV phase if the latter is found to be unreliable (one could also see in FIGS. 8 and 9 that, for some dates, some incidence values have been neither determined nor memorized).

This filtering of the CV phases found to be unreliable allows limiting the number of incidence values to be memorized, and consequently limiting the size of the digital passport of the cell. This also allows avoiding introducing aberrant values in the digital passport of the cell.

The statistical reliability of a CV phase is estimated according to the intrinsic components of the floating current derivative signal obtained for the CV phase.

According to a first example, the statistical reliability of the CV phase is estimated according to an entropy calculated for a sum of the intrinsic components of the floating current derivative signal (for example for the sum of all of the intrinsic components obtained by the EMD decomposition, or for the sum of a predefined maximum number of the first intrinsic components obtained by the EMD decomposition). Different entropy calculation methods may be considered, like for example a Shannon entropy calculation, or a Kolmogorov entropy calculation. For example, the CV phases for which the calculated entropy is too low (lower than a predetermined threshold) are filtered. In particular, a Shannon entropy threshold comprised between 0.25 and 0.5 may be considered.

According to a second example, the statistical reliability of the CV phase is estimated by comparing the total intrinsic energy calculated for the CV phase with a predetermined energy threshold. For example, the CV phases that have an aberrant total intrinsic energy value (higher than the energy threshold) are filtered.

According to still another example, the statistical reliability of the CV phase is estimated by comparing the total intrinsic energy calculated for the CV phase with the total intrinsic energies calculated for all or part of the previous CV phase(s) (for example the total intrinsic energies may be compared with one another, or the total intrinsic energy of the current CV phase may be compared with an average value of total intrinsic energies of previous CV phases). For this purpose, different statistical tests may be considered (Pierce test, Pierson test, etc.).

In particular, the digital passport obtained by the previously-described method 100 may be used to determine whether the cell could, or not, be recycled for a second service life.

For example, it is possible to detect, based on the digital passport, whether the cell has undergone one or more failure(s) over its first service life. The possibility, or not, of reusing the cell in a second service life could then be estimated according to the number and/or the significance of the failures undergone by the cell over its first service life.

For this purpose, and as illustrated in FIG. 1, the method 100 may include an optional step of detecting 170 one or more failure(s) of the cell over its first service life, based on the incidence values memorized in the computer file forming the digital passport of the cell.

According to a first example, the detection of a failure may be implemented by comparing the incidence value with a predetermined incidence threshold, for one or more consecutive CV phase(s).

Nonetheless, other criteria for detecting a failure could be considered. For example, the detection of a failure could be implemented by comparing a distance between an incidence value and an average incidence value with a predetermined distance threshold, for one or more consecutive CV phase(s).

For example, FIGS. 8 and 9 reveal an abnormal behavior of the cell in the month of November 2022. Indeed, the total intrinsic energy (FIG. 8) and total intrinsic spectral density surface area (FIG. 9) values are particularly high during the month of November 2022. This reveals a possible failure of the cell at this period. Furthermore, one could observe that the incidence values take on afterwards lower values compared to the values observed before the month of November 2022. This reveals a premature (or precocious) aging of the cell following the failure of the month of November 2022.

The abnormal behavior of the cell in the month of November 2022 could also be observed on the graphical representations of FIGS. 10 and 11. In FIG. 10, one could also observe a particularly dark color code on the graphical chart starting from the month of November 2022. In FIG. 11, one could observe a change in the position and in the width of the main peak of the spectral density starting from the month of November 2022.

It might be advantageous to know whether some failures undergone by the cell over its first service life are related to the environment in which the cell has evolved. Indeed, failures related to the environment are generally less detrimental to the possibility of reusing the battery in a second service life than failures intrinsic to the cell (for example, failures related to a manufacturing defect or to a precocious degradation of the cell).

For this purpose, and as illustrated in FIG. 1, the method 100 may include an optional step of verifying 180 whether a detected failure is related to the environment in which the cell has evolved.

In particular, this verification 180 may comprise comparing, for a given period, incidence values memorized for the cell during said period with incidence values determined and memorized for at least one other cell subjected to the same environment during said period. If the incidence values observed for one or more other cell(s) subjected to the same environment reveal a similar abnormal evolution during a given period, then it is highly probable that this abnormal behavior is related to the environment (for example because of an exceptional increase in the temperature experienced by the different cells during this period).

In one variant, the verification 180 may comprise comparing, for a given period, environment measurements performed and memorized during said period with a predetermined threshold. For example, it may consist in recording measurements of the temperature to which the cell has been exposed.

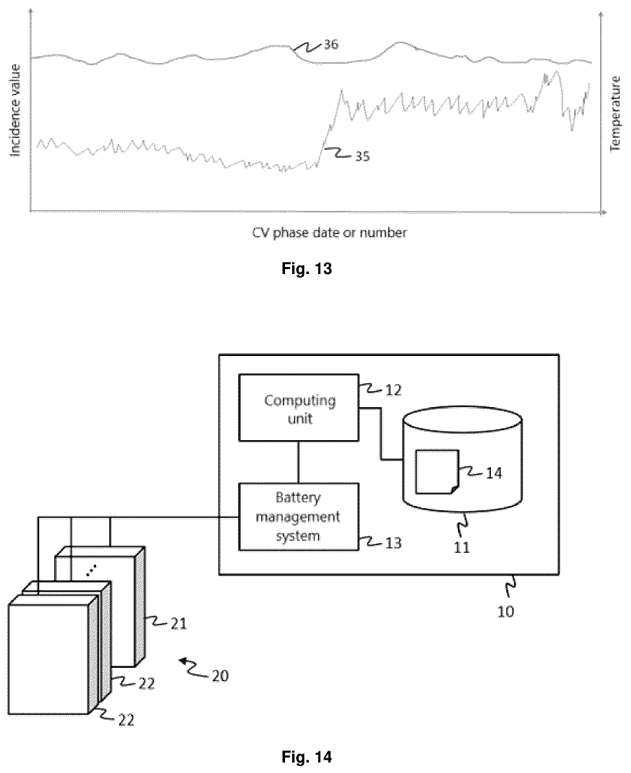

For example, FIGS. 12 and 13 illustrate the evolution over time of the incidence value of a battery cell (curve 35) as well as the evolution over time, during the same period, of the temperature experienced by the cell (curve 36).

In the example illustrated in FIG. 12, the failure evidenced by the incidence value peak is very probably related to the environment because a similar peak is observed at the same time for the temperature experienced by the cell.

However, in the example illustrated in FIG. 13, there is no particular correlation between the evolution of the incidence value and the evolution of the temperature. Hence, the failure evidenced by the abrupt increase in the incidence values does not seem to be related to the environment.

FIG. 14 schematically shows a device 10 for generating a digital passport of a cell 21 of a Lithium-Ion battery 20. In particular, the device 10 includes a memory 11, a battery management system 13 and a computing unit 12 connected to the memory 11 and to the battery management system 13.

The digital passport corresponds to a computer file 14 saved in the memory 11. This computer file 14 includes a set of incidence values representative of a history of states-of-health of the cell 21 over a first service life of the cell 21.

The battery management system is configured to supply current measurements performed at the level of the cell 21 during a CV phase of a CC-CV charging cycle.

The computing unit 12 is configured to implement the method 100 according to any one of the previously-described modes of implementation.

The device 10 may further include a sensor configured to measure the environment (for example a temperature sensor).

The battery management system 13 may also be configured to supply floating current measurements of one or more other cell(s) 22 subjected to the same environment as the cell 21.

The description hereinbefore clearly illustrates that, thanks to its different features and their advantages, the present invention achieves the set objectives. In particular, the evolution of the incidence values observed for the different CV phases of the cell provides a particularly relevant database for estimating its state-of-health and the possibility of reusing it in a second service life.

It should be noted that, for reusing or refurbishing different battery cells in a second service life, it could be considered to pair together cells whose digital passports have similarities. For example, when the incidence value is determined in the form of a spectral density, it is possible to pair together cells having spectral similarities. By pairing cells with the same spectral profile, a greater homogeneity of the battery could be expected in the second service life.

Advantageously, the volume of the data to be memorized to form the digital passport of the cell remains particularly low. Hence, this digital passport could be easily exchanged between different entities interested by the state-of-health of the cell.

1. A method for generating a “digital passport” of a cell of a Lithium-Ion battery, said digital passport being in the form of a computer file including a set of incidence values representative of a history of states-of-health of the cell over a first service life of the cell, the method including, for each “constant-voltage” phase, or CV phase, a set of “constant current-constant voltage” charging cycles, or CC-CV charging cycles, of the cell over its first service life:
collecting a plurality of current measurements taken at the cell during the considered CV phase, said plurality of measurements forming a “floating current” signal,
deriving the floating current signal to obtain a floating current derivative signal,
decomposing into empirical modes the floating current derivative signal in order to obtain therefrom a representation in the form of a sum of a residual signal and of one or more intrinsic component(s),
determining an incidence value representative of a state-of-health of the cell, for the considered CV phase, based on the intrinsic components thus obtained,
memorizing in a computer file the determined incidence value associated with a piece of information on the occurrence time point of the considered CV phase.

2. The method according to claim 1, wherein determining the incidence value, for the considered CV phase, comprises:
calculating an energy for each intrinsic component,
calculating a total intrinsic energy equal to a sum of the energies of the intrinsic components,
determining the incidence value, for the considered CV phase, according to the total intrinsic energy thus calculated.

3. The method according to claim 1, wherein determining the incidence value, for the considered CV phase, comprises:
calculating a spectral density for each intrinsic component,
calculating a total intrinsic spectral density equal to a sum of the spectral densities of the different intrinsic components,
determining the incidence value, for the considered CV phase, according to the total intrinsic spectral density thus calculated.

4. The method according to claim 3, wherein the total intrinsic spectral density is normalized with respect to a maximum value of the total intrinsic spectral density.

5. The method according to claim 3, wherein, for each intrinsic component, the spectral density of the intrinsic component is calculated based on a Hilbert transform of the intrinsic component.

6. The method according to claim 1, further including, for each CV phase, estimating a statistical reliability of the CV phase, according to the intrinsic components of the floating current derivative signal, and filtering the CV phase if the latter is found to be unreliable.

7. The method according to claim 6, wherein the statistical reliability of the CV phase is estimated according to an entropy calculated for a sum of the intrinsic components of the floating current derivative signal.

8. The method according to claim 6, wherein determining the incidence value, for the considered CV phase, comprises:
calculating an energy for each intrinsic component,
calculating a total intrinsic energy equal to a sum of the energies of the intrinsic components,
determining the incidence value, for the considered CV phase, according to the total intrinsic energy thus calculated,
and wherein the statistical reliability of the CV phase is estimated by comparing the total intrinsic energy with a predetermined energy threshold, or with the total intrinsic energies calculated for all or part of the previous CV phases.

9. The method according to claim 1, including a step of detecting at least one failure of the cell over its first service life based on the incidence values memorized in the computer file forming the digital passport of the cell.

10. The method according to claim 9, wherein detecting said at least one failure includes comparing the incidence value with a predetermined incidence threshold, for one or more consecutive CV phase(s).

11. The method according to claim 9, wherein detecting said at least one failure includes comparing a distance between the incidence value and an average incidence value with a predetermined distance threshold, for one or more consecutive CV phase(s).

12. The method according to claim 9, wherein, when at least one failure is detected, the method further includes verifying whether said at least one detected failure is related to the environment in which the cell has evolved.

13. The method according to claim 12, wherein verifying whether said at least one detected failure is related to the environment comprises comparing, for a given period, incidence values memorized for said cell during said period with incidence values determined for at least one other cell subjected to the same environment during said period.

14. The method according to claim 12, wherein verifying whether said at least one detected failure is related to the environment comprises comparing, for a given period, environment measurements performed and memorized during said period with a predetermined threshold.

15. The method according to claim 1, including a step of determining, based on the digital passport of the cell, whether the cell could or could not be reused for a second service life.

16. A device for generating a “digital passport” of a cell of a Lithium-Ion battery, said digital passport being in the form of a computer file including a set of incidence values representative of a history of states-of-health of the cell over a first service life of the cell, said device including:
a memory adapted to memorize the computer file,
a battery management system configured to supply current measurements taken at the cell during a CV phase of a CC-CV charging cycle of the cell,
a computing unit connected to the memory and to the battery management system, said computing unit being configured to implement the method according to claim 1.
